(19) United States
(12) Patent Application Publication
(10) Pub. No.: US 2008/0267426 A1
(43) Pub. Date: Oct. 30, 2008

(54) Device for and a Method of Audio Data Processing

(75) Inventor: Gerrit De Poortere, Leuven (BE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/090,890

(22) PCT Filed: Oct. 19, 2006
(86) PCT No.: PCT/IB2006/053861

§ 371 Date: Apr. 21, 2008

(30) Foreign Application Priority Data
Oct. 24, 2005 (EP) 05109895.2

(51) Int. Cl. H03G 5/00

(52) U.S. Cl. 381/98

(57) ABSTRACT

An audio data processing device (100), comprising a frequency generator (108) adapted to generate a frequency variation signal (107) with a frequency varying in time within a predetermined frequency range, and a processor (106) adapted to generate an audio output signal (109) based on a combination of an audio input signal (104) and the frequency variation signal (107).

### FIELD OF THE INVENTION

The invention relates to an audio data processing device.

The invention further relates to a method of processing audio data.

Moreover, the invention relates to a program element.

Further, the invention relates to a computer-readable medium.

### BACKGROUND OF THE INVENTION

Audio playback devices become more and more important. Particularly, an increasing number of users buy harddisk-based audio/video players and other entertainment equipment.

U.S. Pat. No. 6,134,330 B2 discloses that, to improve the perceived audio signal, it is known to use a harmonics generator to create the illusion that the perceived audio includes lower frequency signal parts than really available. In addition to improving the perceived so called ultra bass signals (for example 20-70 Hz), also the signals in the frequency band between the ultra bass signal and the normal audio signal are improved.

Room modes may occur when audio signals are excited by an audio playback device with a wavelength that has a special relation to the dimensions of the room. Room modes are in fact acoustical standing waves and are the reason that the bass experience of a home cinema system may depend on the position of a sound reproduction device, for example a subwoofer in the room. The smaller the bandwidth that is reproduced by the subwoofer, the more the position dependency of the subwoofer becomes disturbing.

### OBJECT AND SUMMARY OF THE INVENTION

It is an object of the invention to enable audio playback with sufficient audio playback quality.

In order to achieve the object defined above, an audio data processing device, a method of processing audio data, a program element and a computer-readable medium according to the independent claims are provided.

According to an exemplary embodiment of the invention, an audio data processing device is provided, comprising a frequency generator adapted to generate a frequency variation signal with a frequency varying in time within a predetermined frequency range, and a processor adapted to generate an audio output signal based on a combination of an audio input signal and the frequency variation signal.

According to another exemplary embodiment of the invention, a method of processing audio data is provided, the method comprising generating a frequency variation signal with a frequency varying in time within a predetermined frequency range, and generating an audio output signal based on a combination of an audio input signal and the frequency variation signal.

According to still another exemplary embodiment of the invention, a program element is provided, which, when being executed by a processor, is adapted to control or carry out a method of processing audio data having the above mentioned features.

According to yet another exemplary embodiment of the invention, a computer-readable medium is provided, in which a computer program is stored which, when being executed by a processor, is adapted to control or carry out a method of processing audio data having the above mentioned features.

The audio processing according to embodiments of the invention can be realized by a computer program, that is by software, or by using one or more special electronic optimization circuits, that is in hardware, or in hybrid form, that is by means of software components and hardware components.

According to an exemplary embodiment of the invention, a device of processing audio data is provided in which an audio signal—which may be in the bass regime—is manipulated by means of a frequency variation signal. This may modify the bass signal in such a manner that the frequency is slightly varied in time so that problems originating from room modes may be reduced. Namely, by varying the frequency, standing waves formed in a room may be disturbed or brought out of resonance so that these undesired room waves might be weakened without an audible deterioration of the audio signal. Thus, reduced discrete room mode excitation may be achieved.

According to an exemplary embodiment, an enhancing circuit for enhancing an audio signal in an audio system is provided, wherein the enhancing circuit may comprise an input for receiving the audio signal and an envelope detector for detecting an envelope of the audio signal. Furthermore, an oscillator or frequency generator may be provided for generating a single frequency signal. The envelope detector may be designed for adapting the amplitude of the single frequency signal. The oscillator may be designed for changing the frequency of the single frequency signal within a time interval.

The oscillator may be designed as a sweep generator or sweeping oscillator which generates the single frequency signal with constant amplitude, but a frequency that varies over time. Starting at, for example, a time of “0” seconds, the generator single frequency may be 48 Hz. After 0.2 seconds, the frequency may be 50 Hz, and after further 0.2 seconds, the frequency may be 52 Hz. Then, the frequency may go down again and, further 0.4 seconds later, the generator frequency may be back to 48 Hz.

Exemplary applications of embodiments of the invention are any kind of audio products in the field of consumer electronics and automotive. For instance, subwoofer applications like BaryBass are further exemplary fields of applying embodiments of the invention.

“BaryBass” is a technology which has been developed by the company Philips and relates to a miniature, low frequency subwoofer. The BaryBass development may allow for deep bass reproduction from a small loudspeaker enclosure. BaryBass opens up a whole new range of possibilities in adding a true bass sound to integrated flat TV loudspeakers, miniature portable digital audio players, and even in car entertainment systems. A characterizing feature of a BaryBass loudspeaker is that it may operate at its resonant frequency, which means its efficiency can be significantly higher than for a conventional loudspeaker. Such a technology is described, for instance, in WO 2005/027570 A1 to which explicit reference is made hereby.

According to an embodiment of the invention, a method of reducing position dependency due to room modes generated by single tone algorithms is provided. Such a method for enhancing, for instance, BaryBass coverage and effect may be obtained by using a swept sine wave oscillator at bass frequency output, wherein the level is varied with the detected audio signal envelope for woofer/bass signal generation. Furthermore, reduced position dependency (room modes) of bass experience and enhanced audio experience may be achieved.

Algorithms such as BaryBass may generate a single tone which amplitude is related to the energy content of a part of the music spectrum. The generated frequency may be low by definition (for instance 50 Hz). At such low frequencies, room modes start to play an important role in the perception of the bass effect. Room modes are born by the forth and back reflection of acoustic waves against walls, floor and ceiling.

Being in a minimum of a room mode may reduce the perceived effect considerably. Being at a maximum, the effect may sound largely overdone. According to an exemplary embodiment, a method is provided using a swept sine wave with a short sweep time and small frequency band. This method may reduces or eliminate the room mode effect efficiently. Such a system may be used in combination with a synchronous envelope detector. According to an exemplary embodiment of the invention, the excitation of room modes may be significantly reduced. Hence, such undesired standing acoustical waves which may occur when audio signals are played back in a room may be avoided or weakened so that the bass experience of a home cinema system or the like may be made more independent of a position of the subwoofer in the room and may thus be reduced.

The suppressing of the generation of only a single frequency (e.g. 50 Hz) may make the performance of the subwoofer less position-dependent. Thus, an embodiment of the invention may reduce the position dependency by using a swept frequency over a small band (for instance from 48 Hz to 52 Hz).

Next, further exemplary embodiments of the invention will be described. In the following, exemplary embodiments of the audio data processing device will be explained. However, these embodiments also apply for the method of processing audio data, for the program element, and for the computer-readable medium.

The audio data processing device may comprise an audio data supply unit adapted to supply the processor with the audio data input signal(s). Such an audio data supply unit may be connected to or may be formed of an audio data storage unit. Such an audio data storage unit may be a conventional CD or DVD or may also be a harddisk on which the audio data/audio content is stored. Alternatively, such an audio data storage unit may be an audio content database in a network (for example the Internet), in a scenario in which music or other audio content is downloaded from the remote database and is to be played back locally. The audio data supply unit may be a separate unit or may be combined with the audio data storage unit and may be designed in such a manner that it supplies the audio input signal to the processor. The audio data supply unit may also be controlled by a human user by means of a user interface (for instance including a remote control, buttons, a graphical user interface (GUI), or the like) so that the user may control a functionality of the system.

The audio input signal may comprise or may consist of audio signal contributions having a frequency below a threshold frequency. In other words, the audio data processing device may relate to the reproduction of audio data in the low frequency domain, particularly in the bass frequency band. Such a bass frequency band may cover frequencies below essentially 70 Hz, between 20 Hz and 400 Hz, between 20 Hz and 120 Hz, or between 20 Hz and 70 Hz. The term “bass” may particularly denote the lowest part of the human-audible range of audio signals, that is to say the lowest frequencies which are perceivable by the human ear. The term bass may thus describe tones of low frequency.

The frequency generator may be adapted to generate the frequency variation signal with a frequency varying in time with a frequency range having a width of equal or less than approximately 10%, preferably of equal or less than approximately 5%, of a centre frequency. For instance, when the centre frequency is 50 Hz, then the frequency range covered may be between 47.5 Hz to 52.5 Hz or between 48 Hz and 52 Hz. Such a frequency range Δf is relatively narrow with respect to the absolute frequency value f, or in other words Δf/f<<1. This may ensure that the audio perception is not influenced significantly by means of the systematic or specific distortion of standing waves by exemplary embodiments of the invention.

The center frequency may be essentially 50 Hz, which may be advantageous for an application in the context of BaryBass.

The frequency generator may be adapted to generate the frequency variation signal with a frequency periodically varying in time within the predetermined frequency range. With such a periodic variation, a fixed upper and lower limit of the frequency waves may be ensured.

The frequency generator may be adapted to generate the frequency variation signal with essentially a single frequency at a time periodically varying in time within the predetermined frequency range. At a particular moment, the frequency generator may generate a mono-frequency signal. However, at different points of time, the frequency of the mono-frequency signal may be different.

A periodicity according to which the frequency variation signal varies in time may be essentially 200 ms. However, such a periodicity may be also smaller or larger. The ratio between bandwidth (for instance 4 Hz) and the time period respectively periodicity of sweeping the frequency (for instance 200 ms) should be in reasonable correlation. As a rule of thumb, the sweep time should be relatively short, and the frequency span should be relatively small. The periodicity should be selected in such a manner that the human ear does not recognize this oscillating signal as disturbing for the audio quality. Furthermore, the frequency sweeping range should be small enough to be essentially non-perceivable by a human listener.

The frequency generator may be adapted to generate the frequency variation signal with a frequency varying in time according to a saw tooth function or according to a triangle function within the predetermined frequency range. It might be advantageous that the mathematical function defining the variation of the signal is relatively smooth, free of jumps and is not perceived to be disturbing by a human listener. For instance, also a variation with a sine or cosine function or with a (multi-)step function is possible.

The processor may be adapted to generate the audio output signal based on a multiplication of the audio data input signal and the frequency variation signal. By such a multiplication which may be performed by an electronic multiplier unit, the desired effect of disturbing undesired standing waves in a room may be achieved.

The audio data processing device may comprise an audio reproduction unit adapted to reproduce the audio output signal. Such an audio reproduction unit may be a loudspeaker, or can also be an earpiece or a headset.

The processor may be adapted to generate the audio output signal with an amplitude which is essentially constant in time. Technologies like BaryBass may be implemented in an audio data processing device according to an exemplary embodiment of the invention.

The audio data processing device may further comprise a low-pass filter adapted to filter out high-frequency contributions from the audio input signal before supplying the filtered audio input signal to the processor. In other words, audio contributions with frequencies below a threshold value may pass the low-pass filter essentially without attenuation, whereas high frequency contributions above the threshold value may be eliminated by the low-pass filter.

The audio data processing device may further comprise a high-pass filter adapted to filter out low-frequency contributions from the audio input signal before supplying the filtered audio input signal to the processor. In other words, audio contributions with frequencies above a threshold value may pass the high-pass filter essentially without attenuation, whereas low frequency contributions below the threshold value may be eliminated by the high-pass filter. The threshold value of the high-pass filter may differ from the threshold value of the low-pass filter. By means of such a high-pass filter, a loudness compensation may be performed which may also have the consequence that distortions are reduced so that the audio quality may be improved. The high-pass filter may simulate the ear sensitivity curve for the low frequencies. Without such a filter, a 20 Hz input signal would be projected to the center frequency (e.g. 50 Hz) equally loud an input signal of a frequency of 40 Hz. But the ear is less sensitive to 20 Hz, hence it would sound overdone. To temper this effect, the high-pass filter may be included.

The audio data processing device may further comprise an envelope detector adapted to detect an envelope of the audio input signal and to adapt an amplitude of the frequency variation signal based on the detected envelope of the audio input signal. By taking this measure, a synchronous envelope detector may be provided by means of which an envelope of the audio input signal may be detected. Such an envelope may contain information concerning or may be indicative of an amplitude of the audio input signal. This information can be used to control the frequency generator so that the generated frequency variation signal (auxiliary signal) may reflect the frame conditions of the envelope. Particularly, the strength or intensity of the (single frequency) auxiliary signal may be adjusted in such a manner as to be in accordance with the envelope properties of the audio input signal.

The audio data processing device may be a subwoofer, a DVD player, a CD player, a harddisk-based media player, an internet radio device, a public entertainment device, an MP3 player, a vehicle entertainment device, a car entertainment device, a portable audio player, a portable video player, a mobile phone, a medical communication system, a body-worn device, or a hearing aid device. A “subwoofer” may be denoted as a loudspeaker for selective reproduction of low frequencies, particularly bass frequencies. A “car entertainment device” may be a hi-fi system for an automobile.

However, although the system according to embodiments of the invention primarily intends to improve the quality of sound or audio data, it is also possible to apply the system for a combination of audio data and visual data. For instance, an embodiment of the invention may be implemented in audiovisual applications like a video player in which a loudspeaker and/or a subwoofer is used, or a home cinema system.

The aspects defined above and further aspects of the invention are apparent from the examples of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 shows an audio data processing device according to an exemplary embodiment of the invention.

FIG. 2 shows a diagram illustrating a time dependence of a frequency signal of a sweep generator according to an exemplary embodiment of the invention.

FIG. 3 shows an audio data processing device according to an exemplary embodiment of the invention.

FIG. 4 shows a room in which an audio data processing device according to an exemplary embodiment of the invention may be operated.

### DESCRIPTION OF EMBODIMENTS

The illustration in the drawing is schematically. In different drawings, similar or identical elements are provided with the same reference signs.

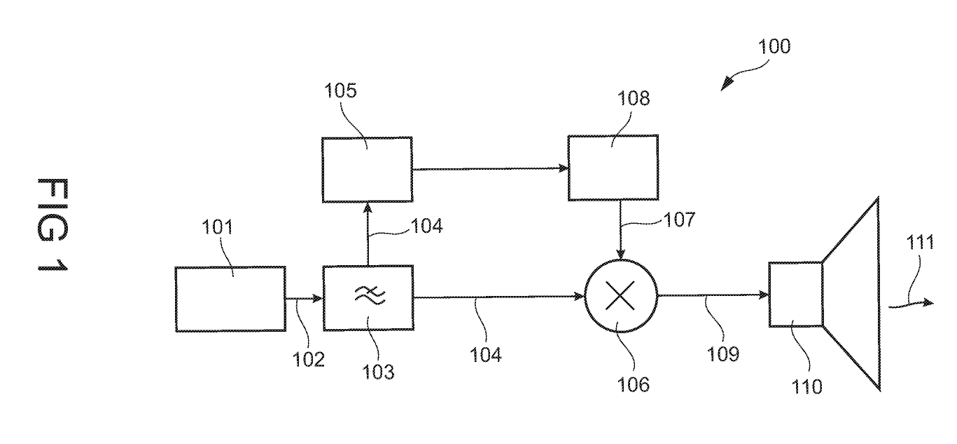

In the following, referring to FIG. 1, an audio data processing device 100 according to an exemplary embodiment of the invention will be described.

The audio data processing device 100 in the present case is adapted as a HiFi device and comprises a harddisk 101 (alternatives are a CD, a DVD, etc.) as an audio data storage unit. On the harddisk 101, audio data are stored, for instance different items of music, movies, audio books or the like. When the audio data processing device 100 is activated, for instance when a user operates a switch on the device 100 or presses a play button, audio signals 102 are supplied from the harddisk 101 to a low pass filter 103.

The low pass filter 103 filters out high frequency components of the audio signal, for instance components above an adjustable value of 70 Hz. At the output of the low pass filter 103, so-called audio input signals 104 are provided and supplied to both, an envelope detector 105 and a multiplier unit 106. The low pass filter 103 may be substituted by a band pass filter. The audio input signal 104 may comprise audio signals in the bass regime, for instance between 20 Hz and 70 Hz.

The envelope detector 105 detects an envelope of the audio input signal 104 and controls a frequency generator 108 to adjust an amplitude of a frequency variation signal 107 generated by the frequency generator 108 to a value which is defined by the detected envelope of the audio input signal 104.

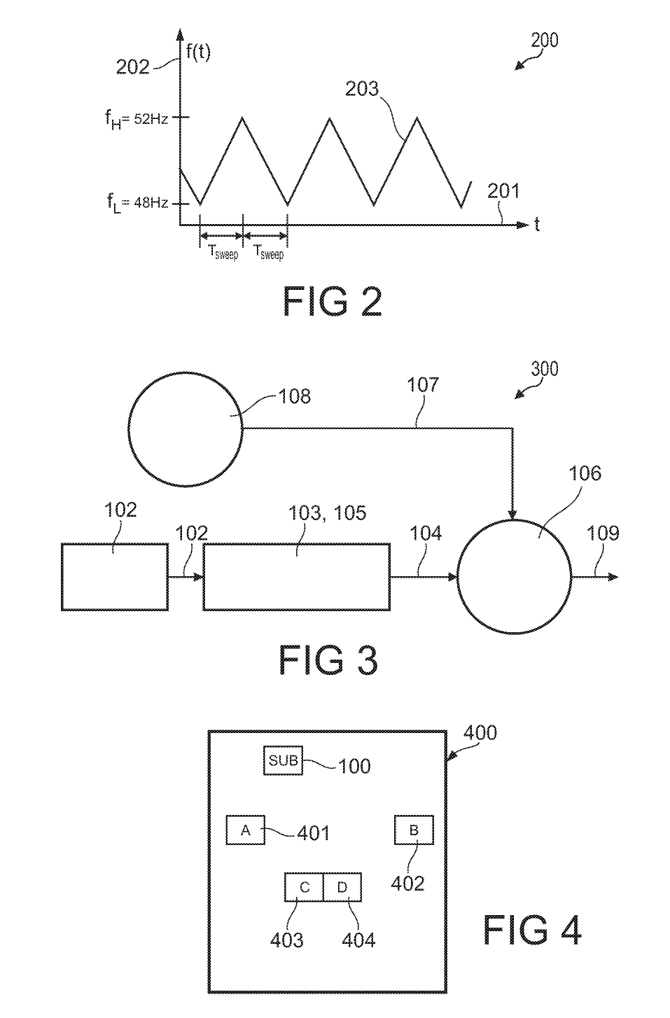

In more detail, the frequency generator 108 generates a frequency variation signal 107 with a frequency varying in time within a predetermined frequency range. For instance, the frequency generated by the frequency generator 108 varies between 48 Hz and 52 Hz. These minimum and maximum frequency values are connected by means of a saw tooth function with teeth that are repeated every 0.4 seconds (see FIG. 2).

Furthermore, the multiplier unit 106, which may also be denoted as a processor unit (for instance a microprocessor, CPU), is adapted to generate an audio output signal 109 based on a multiplication of the audio input signal 104 and the frequency variation signal 107.

As can be taken from FIG. 1, the audio data processing device 100 comprises a loudspeaker 110 which reproduces the audio output signal 109 and generates acoustic waves 111 which are audible by a human listener (not shown in the figure).

When the audio data processing device 100 is adapted as a subwoofer in a room, the excitation of standing acoustic waves based on a correlation of dimensions of the room and the frequency of the audio bass components may be avoided, eliminated or reduced, since the sweeping oscillator 108 slightly modifies the played back frequencies in time so that a resonance condition is selectively distorted.

In the following, referring to FIG. 2, a diagram 200 will be explained.

Along an abscissa 201 of the diagram 200, the time t is plotted. Along an ordinate 202, the frequency f(t) of a frequency variation signal 203 is plotted in dependence of the time t. This frequencies sampled by the curve 203 are between a low frequency limit f_{L}=48 Hz and a high frequency limit f_{H}=52 Hz, that is within a range of ±2 Hz around the center frequency of 50 Hz. FIG. 2 therefore shows the time dependence of the frequency variation signal 203, that is the time dependence of the frequency of the frequency variation signal 107 as produced by the generator 108.

T_{sweep} is the sweep time to go linearly from f_{L} to f_{H} or from f_{H} to f_{L}. This sweep time in the present case is 200 ms. Another sweeptime may be possible, for example 100 ms or 400 ms.

As can be taken from FIG. 2, the function f(t) 203 is a saw tooth signal. Referring to FIG. 2, the swept signal generator 108 generates the frequency variation signal 107 with a small bandwidth of 4 Hz, swept over time period of 200 ms. As the sweep generator 108 generates succeeding frequencies, a slightly different location in the room in which the subwoofer 100 is used will be excited, and a kind of “smearing” effect occurs. In other words, standing waves are smeared out so that the disturbing effect originating from such acoustical standing waves is reduced and the audio quality is improved.

The sweep generator 108 generates a constant amplitude, by a frequency which is time dependent. During such a procedure, starting at, for instance, “0” seconds, the generated frequency is 48 Hz. After an interval of 0.2 seconds, the frequency is 50 Hz and after a further interval of 0.2 seconds, the frequency is 52 Hz. The frequency goes down again and after further 0.4 seconds, the generator's 108 frequency is back to 48 Hz. Then the procedure starts again.

In the following, referring to FIG. 3, an audio data processing device 300 according to an exemplary embodiment of the invention will be described.

FIG. 3 shows the application of the sweep generator 108 in the context of an algorithm to reduce discrete room mode excitation.

For this purpose, a music signal 102 stored in and reconditioned by an audio data storage device 101 is supplied to a combined unit 103, 105 including a low pass filter and an envelope detector. The audio input signal 104 provided at an output of the combined low pass filter an envelope detector unit 103, 105 is provided to an input of a multiplier unit 106 that receives, at another input, the frequency variation signal 107. Based on the frequency variation signal 107 and the audio input signal 104, the audio output signal 109 is generated for reproduction.

Coming back to FIG. 2, the function f(t) can be expressed mathematically as indicated as follows:

$$\begin{matrix}If \text{:} & \\ t mod ( 2 \cdot {T}_{sweep} ) < {T}_{sweep} \\ then & ( 1 ) \\ f ( t ) = {f}_{L} + ( {f}_{H} - {f}_{L} ) \cdot \frac{( t mod {T}_{sweep} )}{{T}_{sweep}} \\ else \text{:} & ( 2 ) \\ f ( t ) = {f}_{H} + ( {f}_{H} - {f}_{L} ) \cdot \frac{( t mod {T}_{sweep} )}{{T}_{sweep}} & ( 3 )\end{matrix}$$

Wherein the term “mod” expressed the modulo operation. Table 1 gives an example of values of T_{sweep}, F_{L} and f_{H}:

TABLE 1

| Tsweep | 0.2s |
|---|---|
| f_{L} | 48 |
| f_{H} | 52 |

According to the formulas (1) to (3) and the values of table 1, this results in time and frequency values of table 2:

TABLE 2

| Time t (seconds) | Frequency f(t) (Hz) |
|---|---|
| 0 | 48 |
| 0.1 | 50 |
| 0.15 | 51 |
| 0.19 | 51.8 |
| 0.2 | 52 |
| 0.21 | 51.8 |
| 0.3 | 50 |
| 0.35 | 49 |
| 0.39 | 48.2 |
| 0.4 | 48 |
| 0.5 | 50 |
| 0.55 | 51 |
| 0.59 | 51.8 |
| 0.6 | 52 |
| 0.61 | 51.8 |
| 0.7 | 50 |
| 0.75 | 49 |
| 0.79 | 48.2 |
| 0.8 | 48 |

In the following, referring to FIG. 4, it will be explained how a subwoofer 100 can be operated within a room 400 with respect to first to fourth seating positions 401 to 404.

Measurements with such a home living room 400 have been performed at several seating positions, named A to D (reference numerals 401 to 404). The SPL (sound pressure level), which is a measure of strength or intensity of sound, was recorded when reproducing 48 Hz, 50 Hz, 52 Hz and a sweep of 48 to 52 Hz with a sweep time of 0.2 seconds.

The SPL when applying a sweep is more constant over the several positions than when a discrete tone is applied.

The results of the measurement are shown in Table 3.

TABLE 3

| | 48 Hz | 50 Hz | 52 Hz | Sweep |
|---|---|---|---|---|
| Pos. A | 75 dB | 67 dB | 76 dB | 75 dB |
| Pos. B | 80 dB | 60 dB | 71 dB | 74 dB |
| Pos. C | 81 dB | 74 dB | 65 dB | 77 dB |
| Pos. D | 80 dB | 70 dB | 67 dB | 75 dB |

It should be noted that the term “comprising” does not exclude other elements or steps and the “a” or “an” does not exclude a plurality. Also elements described in association with different embodiments may be combined. It should also be noted that reference signs in the claims shall not be construed as limiting the scope of the claims.

1. An audio data processing device (100), comprising
a frequency generator (108) adapted to generate a frequency variation signal (107) with a frequency varying in time within a predetermined frequency range;
a processor (106) adapted to generate an audio output signal (109) based on a combination of an audio input signal (104) and the frequency variation signal (107).

2. The audio data processing device (100) according to claim 1,
comprising an audio data supply unit (101) adapted to supply the processor (106) with the audio input signal (104).

3. The audio data processing device (100) according to claim 1,
wherein the audio input signal (104) consists of audio signal contributions having a frequency below a threshold frequency.

4. The audio data processing device (100) according to claim 1,
wherein the audio input signal (104) consists of audio signal contributions having a frequency in a bass frequency band.

5. The audio data processing device (100) according to claim 1,
wherein the audio input signal (104) consists of audio signal contributions having a frequency in a frequency band of the group consisting of a frequency band below essentially 70 Hz, a frequency band between essentially 20 Hz and essentially 120 Hz, and a frequency band between essentially 20 Hz and essentially 70 Hz.

6. The audio data processing device (100) according to claim 1,
wherein the frequency generator (108) is adapted to generate the frequency variation signal (107) with a frequency varying in time within a frequency range having a width of less than or equal 10%, preferably of less than or equal 5%, of a center frequency.

7. The audio data processing device (100) according to claim 6,
wherein the center frequency is in the range between essentially 20 Hz and essentially 70 Hz, preferably essentially 50 Hz.

8. The audio data processing device (100) according to claim 1,
wherein the frequency generator (108) is adapted to generate the frequency variation signal (107) with a frequency which is varying periodically in time within the predetermined frequency range.

9. The audio data processing device (100) according to claim 1,
wherein the frequency generator (108) is adapted to generate the frequency variation signal (107) with essentially a single frequency at a time which is varying periodically in time within the predetermined frequency range.

10. The audio data processing device (100) according to claim 1,
wherein a periodicity according to which the frequency variation signal (107) varies in time is essentially 200 ms.

11. The audio data processing device (100) according to claim 1,
wherein the frequency generator (108) is adapted to generate the frequency variation signal (107) with a frequency varying in time according to at least one of the group consisting of a saw tooth function, a triangle function, and a step function.

12. The audio data processing device (100) according to claim 1,
wherein the processor (106) is adapted to generate the audio output signal (109) based on a multiplication of the audio input signal (104) and the frequency variation signal (107).

13. The audio data processing device (100) according to claim 1,
comprising an audio reproduction unit (110) adapted to reproduce the audio output signal (109).

14. The audio data processing device (100) according to claim 1,
wherein the processor (106) is adapted to generate the audio output signal (109) with an amplitude or an intensity being essentially constant in time.

15. The audio data processing device (100) according to claim 1,
comprising a low-pass filter (103) adapted to low-pass filter the audio input signal (102) before supplying a filtered audio input signal (104) to the processor (106).

16. The audio data processing device (100) according to claim 1,
comprising a high-pass filter adapted to high-pass filter the audio input signal (102) before supplying a filtered audio input signal (104) to the processor (106).

17. The audio data processing device (100) according to claim 1,
comprising an envelope detector (105) adapted to detect an envelope of the audio input signal (104) and to adapt an amplitude of the frequency variation signal (107) based on the detected envelope of the audio input signal (104).

18. The audio data processing device (100) according to claim 1,
realized as at least one of the group consisting of a subwoofer, a DVD player, a CD player, a harddisk-based media player, an internet radio device, a public entertainment device, an MP3 player, a vehicle entertainment device, a car entertainment device, a portable audio player, a portable video player, a mobile phone, a medical communication system, a body-worn device, and a hearing aid device.

19. A method of processing audio data,
the method comprising:
generating a frequency variation signal (107) with a frequency varying in time within a predetermined frequency range;
generating an audio output signal (109) based on a combination of an audio input signal (104) and the frequency variation signal (109).

20. A program element, which, when being executed by a processor, is adapted to control or carry out a method of processing audio data, the method comprising:
generating a frequency variation signal (107) with a frequency varying in time within a predetermined frequency range;
generating an audio output signal (109) based on a combination of an audio input signal (104) and the frequency variation signal (107).

21. A computer-readable medium, in which a computer program is stored which, when being executed by a processor, is adapted to control or carry out a method of processing audio data, the method comprising:
generating a frequency variation signal (107) with a frequency varying in time within a predetermined frequency range;
generating an audio output signal (109) based on a combination of an audio input signal (104) and the frequency variation signal (107).
